(19) United States
(12) Patent Application Publication
(10) Pub. No.: US 2008/0239664 A1
(43) Pub. Date: Oct. 2, 2008

(54) HEAT DISSIPATING SYSTEM FOR COMPUTER

(75) Inventors: ZHENG SUN, Shenzhen (CN); YAN LI, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/778,095

(22) Filed: Jul. 16, 2007

(30) Foreign Application Priority Data
Mar. 27, 2007 (CN) 200720200183.7

(51) Int. Cl. H05K 7/20

(52) U.S. Cl. 361/692; 361/695

(57) ABSTRACT

A heat dissipating system is used for dissipating heat from a computer enclosure. The computer enclosure includes a front plate, a rear plate, and a side plate connected between the front and rear plates. First and second heat dissipating devices are accommodated in the enclosure. A motherboard is mounted on the side plate. A plurality of interface cards is mounted on the motherboard. The interface cards are located between the first and second heat dissipating devices.

### BACKGROUND

1. Field of the Invention

The present invention relates to a heat dissipating system for a computer, and more particularly to a heat dissipating system which is capable of cooling most of the components in a computer.

2. Description of Related Art

Various electrical instruments nowadays, and especially the desktop computer, are crowded with different electrical components and peripheral devices, such as the central processing unit (CPU), the interface card, the data storage devices, and the power supply. These electrical components and peripheral devices generate heat during operation. The inner temperature of the desktop computer enclosure can become very high. Therefore, one or more heat dissipation devices are installed inside the computer chassis to remove the heat generated by the electrical components and peripheral devices, to ensure that the inside of the computer chassis maintains a moderate operating temperature.

FIG. 1 shows a typical ATX computer system which includes an ATX type motherboard 20, and an ATX type computer enclosure 10. The enclosure 10 includes a front plate 11, a rear plate 13, and a right side plate 15 formed between the front plate 11 and the rear plate 13. A left side of the enclosure 10 defines an opening, and a left side cover (not shown) can be mounted thereon to cover the opening. An upper portion of the rear plate 13 defines an opening (not shown), and a power supply 131 is mounted on the rear plate 13 corresponding to the opening of the rear plate 13. A fan (not shown) of the power supply 131 dissipates heat generated by the power supply 131 and aids dissipating heat from within the enclosure 10 via the opening of the rear plate 13. A plurality of vent holes (not shown) is defined in the rear plate 13 below the power supply 131, and a fan 135 is mounted on the rear plate 13 to cover the vent holes for dissipating heat in the enclosure 10. A plurality of slots 133 is defined in the rear plate 13 below the vent holes adapted for exposing I/O ports of different interface cards of the motherboard 20 outside of the enclosure 10.

The ATX type motherboard 20 is mounted on the right side plate 15. The motherboard 20 includes a CPU with a hest sink and a fan 23 attached thereon. The heat sink and the fan 23 are located at a generally same height as the fan 135 to remove heat generated by the CPU. A plurality of interface cards 25 are mounted on the motherboard 20, and aligned with the slot 133 of the rear plate 13 to expose the I/O ports outside. However, in the above computer system, the fans 135, 23 and the fan of the power supply 131 are located at the upper portion of the enclosure 10. The lower portion of the enclosure 10 where the interface cards 25 are located doesn't have any fans or other heat dissipating devices to help dissipate heat.

FIG. 2 shows a typical BTX computer system. which includes a BTX type motherboard 40, and a BTX type computer enclosure 30. The enclosure 30 includes a front plate 31, a rear plate 33, and a left side plate 35 formed between the front plate 31 and the rear plate 33. A right side of the enclosure 30 defines an opening, and a right side cover (not shown) can be mounted thereof to cove the opening. An upper portion of the rear plate 33 defines an opening (not shown), and a power supply 331 is mounted on the rear plate 33 corresponding to the opening of the rear plate 33. A fan (not shown) in the power supply 331 dissipates heat generated by the power supply 331 and aids dissipating heat from within the enclosure 30 via the opening of the rear plate 33. A plurality of vent holes (not shown) is defined in the rear plate 33 below the power supply 331, and a fan 335 is mounted on the rear plate 33 to cover the vent holes for dissipating heat in the enclosure 30. A plurality of slots 333 is defined in the rear plate 33 below the vent holes adapted for exposing I/O ports of different interface cards of the motherboard 40 outside of the enclosure 30.

The BTX type motherboard 40 is mounted on the left side plate 35. The motherboard 40 includes a CPU with a hest sink and a fan 43 attached thereon. The heat sink and the fan 43 are located at a generally same height as the fan 335 to remove heat generated by the CPU. A plurality of interface cards 45 are mounted on the motherboard 20, and aligned with the slot 333 of the rear plate 33 to expose the I/O ports outside. In the above computer system, the fans 335, 43 and the fan of the power supply 331 are located at the upper portion of the enclosure 30. As can be seen, components of the BTX computer system are similarly arranged as in the ATX system, therefore the lower portion of the enclosure 30 where the interface cards 35 are located also doesn't have any fans or other heat dissipating devices to help dissipate heat.

### SUMMARY

A heat dissipating system is used for dissipating heat from a computer enclosure. The computer enclosure includes a front plate, a rear plate, and a side plate connected between the front and rear plates. First and second heat dissipating devices are accommodated in the enclosure. A motherboard is mounted on the side plate. A plurality of interface cards is mounted on the motherboard. The interface cards are located between the first and second heat dissipating devices.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an isometric view of a conventional heat dissipating system in a conventional ATX type computer;

FIG. 2 is an isometric view of a conventional heat dissipating system in a conventional BTX type computer;

FIG. 3 is an isometric view of a heat dissipating system in accordance with a preferred embodiment of the present invention;

FIG. 4 is another isometric view of the heat dissipating system in FIG. 3, viewed from another aspect; and

FIG. 5 is an isometric view of a heat dissipating system in accordance with a second preferred embodiment of the present invention.

### DETAILED DESCRIPTION OF THE EMBODIEMNTS

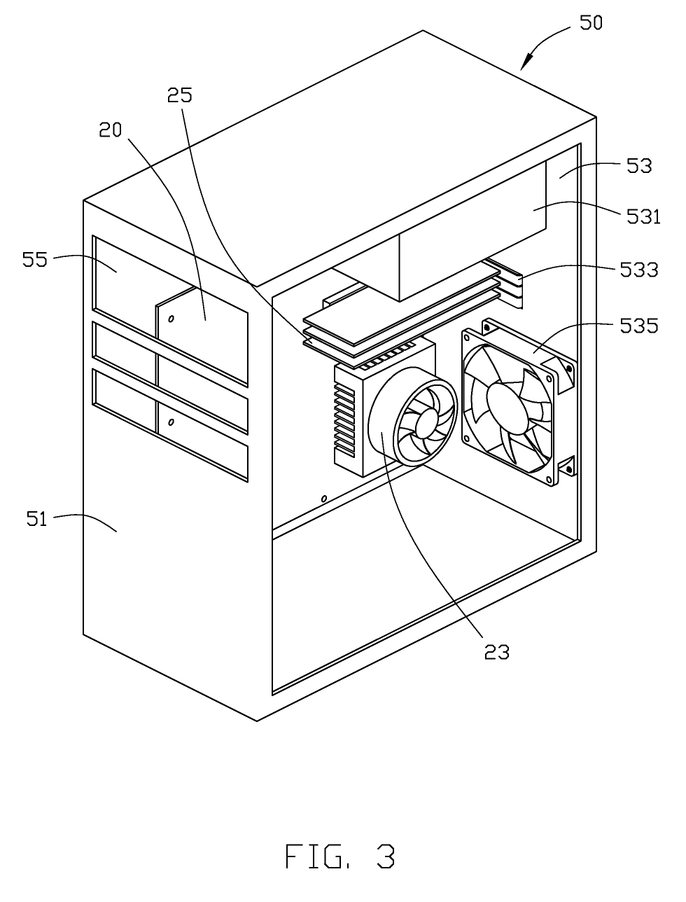

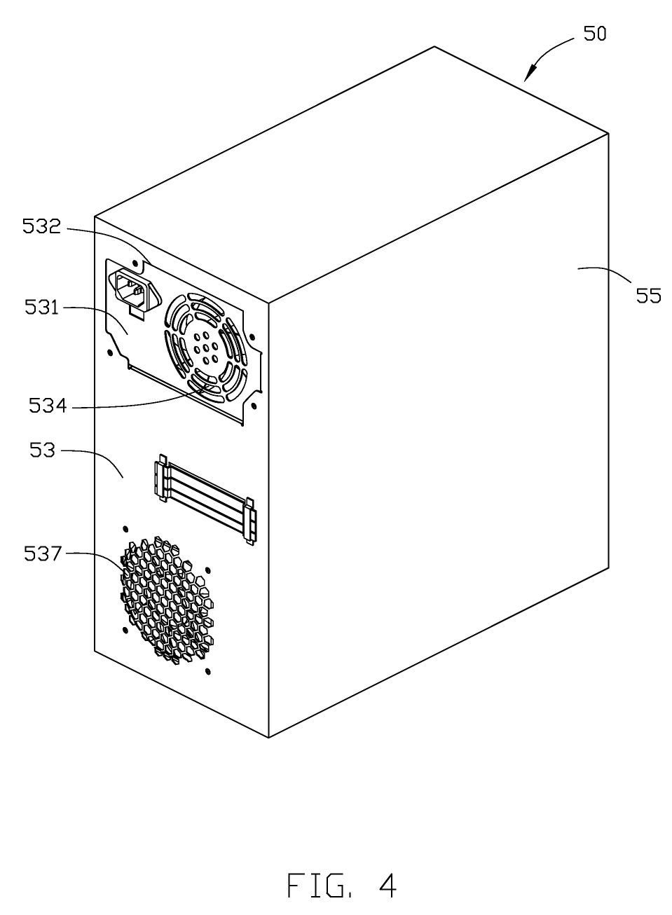

Referring to FIGS. 3 and 4, a first preferred embodiment of the heat dissipating system for a computer is shown. The computer comprises a computer enclosure 50. The enclosure 50 includes a front plate 51, a rear plate 53, and a left side plate 55 formed between the front plate 51 and the rear plate 53. A right side of the enclosure 50 defines an opening, and a right side cover (not shown) can be mounted thereon to cover the opening. An upper portion of the rear plate 53 defines an opening 532, and a power supply 531 is mounted on the rear plate 53 corresponding to the opening 532. A fan 534 in the power supply 531 dissipates heat generated by the power supply 531 and heat from within the enclosure 50 via the opening 532 of the rear plate 53. A plurality of slots 533 is defined in the rear plate 53 below the power supply 531. A plurality of vent holes 537 is defined below the slots 533, and a fan 535 is mounted on the rear plate 53 to cover the vent holes 537 for dissipating heat in the enclosure 50.

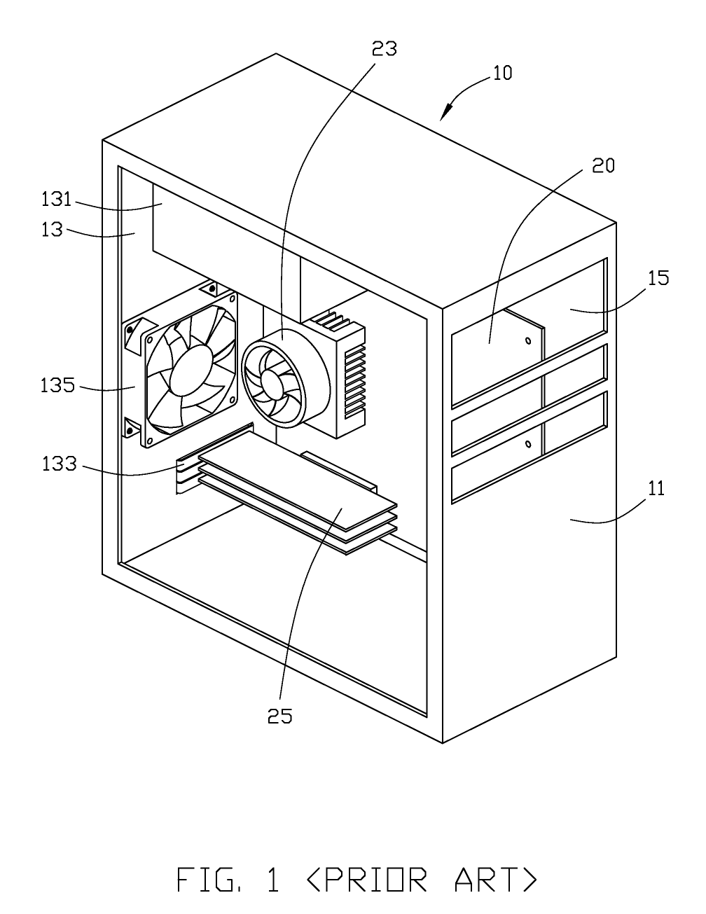

The ATX type motherboard 20 of FIG. 1 is rotated 180 degrees around a horizontal axis to have the CPU and the fan 23 located below the interface cards 25. The motherboard 20 is then mounted on the left side plate 55 of the enclosure 20. The interface cards 25 on the motherboard 20 are corresponding to the slots 533, and I/O ports of the interface cards 25 are exposed outside the enclosure 50 via the slots 533. The CPU and the fan 23 are located at a generally same height as the fan 535 to efficiently remove heat generated by the CPU. In the above computer, the interface cards 25 are located between the fans 534 and 535. Therefore, the heat generated by the interface cards 25 can be dissipated by the fans 534 and 535. The heat dissipating system in the above computer is efficient to dissipate heat for most of the components in the computer.

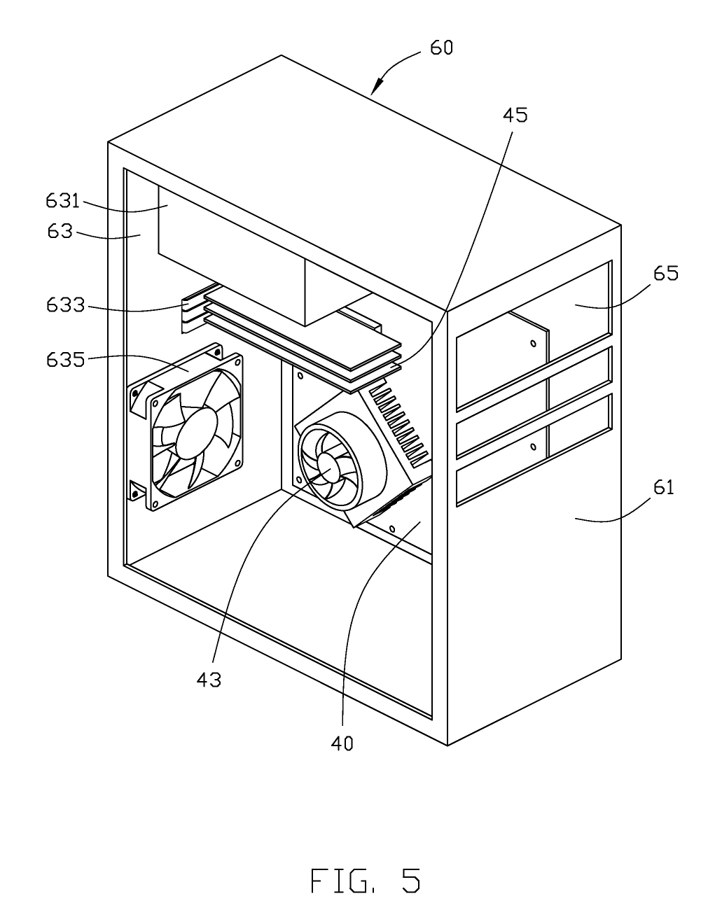

Referring to FIG. 5, a second preferred embodiment of the heat dissipating system for a computer is shown. The computer includes a computer enclosure 60. The enclosure 60 includes a front plate 61, a rear plate 63, and a right side plate 65 formed between the front plate 61 and the rear plate 63. A left side of the enclosure 60 defines an opening, and a left side cover (not shown) can be mounted thereof to cove the opening. An upper portion of the rear plate 63 defines an opening (not shown), and a power supply 631 is mounted on the rear plate 63 corresponding to the opening of the rear plate 63. A fan in the power supply 631 dissipates heat generated by the power supply 631 and within the enclosure 60 via the opening of the rear plate 631. A plurality of slots 633 is defined in the rear plate 63 below the power supply 631. A plurality of vent holes is defined below the slots 633, and a fan 635 is mounted on the rear plate 63 to cover the vent holes for dissipating heat in the enclosure 60.

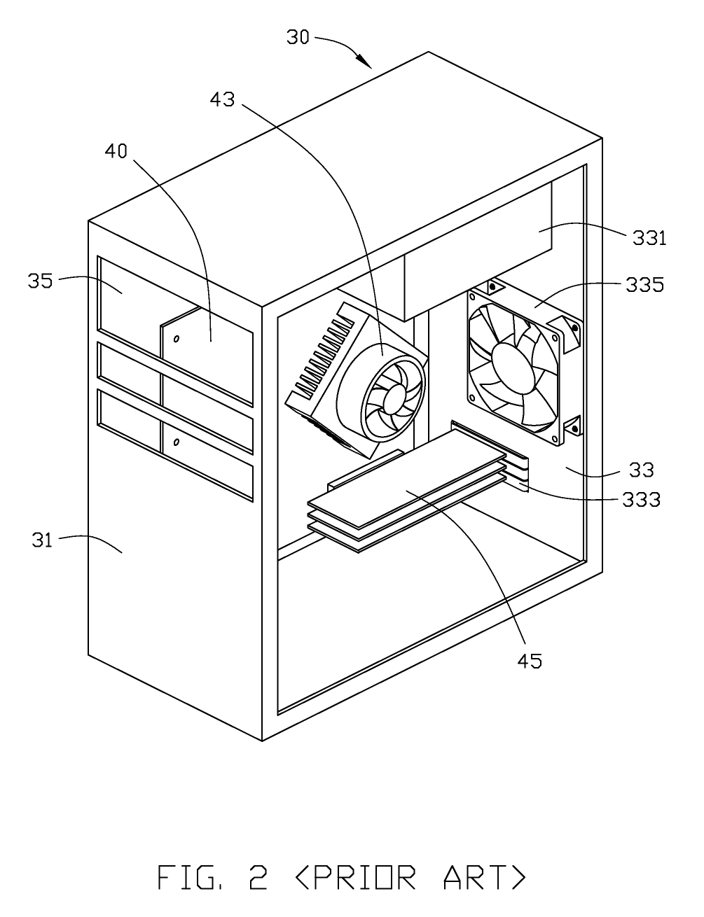

The BTX type motherboard 40 of FIG. 2 is rotated 180 degrees around a horizontal axis to have the CPU and the fan 43 located below the interface cards 45. The motherboard 40 is then mounted to the right side plate 65 of the enclosure 60. The interface cards 45 on the motherboard 40 are corresponding to the slots 633, and I/O ports of the interface cards 45 are exposed outside the enclosure 60 via the slots 633. The CPU and the fan 43 are aligned at a substantially same height as the fan 635 to efficiently remove heat generated by the CPU. In the above computer, the interface cards 45 are located between the fan 635 and the fan of the power supply 631. Therefore, the heat generated by the interface cards 45 can be dissipated by the fan 635 and the fan of the power supply 631. The heat dissipating system in the above computer is efficient to dissipate heat for most of the components in the computer.

In the above two embodiments, the interface cards on the motherboards are located between two heat dissipating devices, such as cooling fans, so the interface cards can be better cooled.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipating system for dissipating heat from a computer, comprising:
a computer enclosure comprising a front plate, a rear plate, and a side plate connected between the front and rear plates;
a first heat dissipating device and a second heat dissipating device accommodated in the enclosure;
a motherboard mounted on the side plate; and
a plurality of interface cards mounted on the motherboard, the interface cards being located between the first and second heat dissipating devices.

2. The heat dissipating system as described in claim 1, comprising a power supply module adjacent to an upper portion of the rear plate, the first heat dissipating device includes a fan arranged in the power supply module.

3. The heat dissipating system as described in claim 2, wherein an opening is defined in the upper portion of the rear plate, the fan being disposed adjacent to the opening in the upper portion of the rear plate.

4. The heat dissipating system as described in claim 3, wherein a plurality of vent holes is defined in a lower portion of the rear plate, and the second heat dissipating device includes an enclosure fan mounted on the lower portion of the rear plate covering the vent holes.

5. The heat dissipating system as described in claim 4, wherein the rear plate defines a plurality of slots between the opening and the vent holes, and I/O ports of the interface card are disposed outside the enclosure via the slots.

6. The heat dissipating system as described in claim 4, wherein a CPU is attached on the motherboard, and a CPU fan is mounted on the CPU at a substantially same height as the enclosure fan.

7. The heat dissipating system as described in claim 1, wherein the motherboard is an ATX type motherboard, and the side plate is a left side plate of the enclosure.

8. The heat dissipating system as described in claim 1, wherein the motherboard is a BTX type motherboard, and the side plate is a right side plate of the enclosure.

9. A heat dissipating system, comprising:
an enclosure defining a plurality of holes therein for communicating an interior and an exterior of the enclosure;
a first heat dissipating device and a second heat dissipating device mounted in the enclosure corresponding to the holes for dissipating heat from the enclosure via the holes;
a motherboard mounted in the enclosure; and
at least one interface card mounted on the motherboard, the at least one interface card being located between the first and second heat dissipating devices.

10. The heat dissipating system as described in claim 9, wherein the enclosure comprises a front plate, a rear plate, and a side plate connected between the front and rear plates, the motherboard being mounted on the side plate.

11. The heat dissipating system as described in claim 10, comprising a power supply module adjacent to an upper portion of the rear plate, the first heat dissipating device includes a fan arranged in the power supply module.

12. The heat dissipating system as described in claim 1, wherein an opening is defined in the upper portion of the rear plate, the fan being disposed adjacent to the opening in the upper portion of the rear plate.

13. The heat dissipating system as described in claim 12, wherein a plurality of vent holes is defined in a lower portion of the rear plate, and the second heat dissipating device includes an enclosure fan mounted on the lower portion of the rear plate covering the vent holes.

14. The heat dissipating system as described in claim 13, wherein the rear plate defines a plurality of slots between the opening and the vent holes, and I/O ports of the interface card are disposed outside the enclosure via the slots.

15. The heat dissipating system as described in claim 13, wherein a CPU is attached on the motherboard, and a CPU fan is mounted on the CPU at a substantially same height as the enclosure fan.

16. The heat dissipating system as described in claim 9, wherein the motherboard is an ATX type motherboard, and the side plate is a left side plate of the enclosure.

17. The heat dissipating system as described in claim 9, wherein the motherboard is a BTX type motherboard, and the side plate is a right side plate of the enclosure.

18. A heat dissipating system comprising:
a computer enclosure comprising a front plate, a rear plate, and a side plate connected between the front and rear plates;
a power supply module arranged in the computer enclosure, adjacent to an upper portion of the rear plate;
a fan arranged in the power supply module;
a motherboard mounted on the side plate;
a heat dissipating device mounted on the rear plate; and
a plurality of interface cards mounted on the motherboard, the interface cards being located between the fan and the heat dissipating device.

19. The heat dissipating system as described in claim 18, wherein the heat dissipating device is mounted on the rear plate in a manner such that the motherboard are free of the interface cards located below the heat dissipating device.
